(19) United States
(12) Patent Application Publication
(10) Pub. No.: US 2006/0145362 A1
(43) Pub. Date: Jul. 6, 2006

(54) Semiconductor package and fabrication method of the same

(76) Inventors: Chin-Huang Chang, Taichung (TW); Chih-Ming Huang, Taichung (TW); Chien-Ping Huang, Taichung (TW); Cheng-Hsu Hsiao, Taichung (TW)

Correspondence Address: Mr. Joseph A. Sawyer, Jr.;SAWYER LAW GROUP LLP, Suite 406, 2465 East Bayshore Road, Palo Alto, CA, 94303, US

(21) Appl. No.: 11/207,472

(22) Filed: Aug. 18, 2005

(30) Foreign Application Priority Data
Jan. 6, 2005 (TW) 094100326

(51) Int. Cl. H01L 23/28

(52) U.S. Cl. 257/787

(57) ABSTRACT

A semiconductor package and a fabrication method of the same are proposed. A chip formed with a plurality of electrode pads on an active surface thereof, and a substrate having a first surface, a corresponding second surface and at least one opening penetrating therethrough are provided. A part of the electrode pads of the chip are electrically connected to the second surface of the substrate by bonding wires passing through the opening of the substrate, and the rest of the electrode pads of the chip are electrically connected to the first surface of the substrate by conductive bumps. A molding process is performed to form a first encapsulant on the first surface of the substrate for encapsulating the chip and form a second encapsulant on the second surface of the substrate for encapsulating the bonding wires. A plurality of solder balls are implanted on the second surface of the substrate.

### FIELD OF THE INVENTION

The present invention relates to semiconductor packages and fabrication methods of the same, and more particularly, to a window-type ball grid array (WBGA) semiconductor package and a fabrication method of the WBGA semiconductor package.

### BACKGROUND OF THE INVENTION

Semiconductor package is an electronic device carrying active components such as semiconductor chips, which comprises at least one chip mounted on a side of a substrate and electrically connected to the substrate via a plurality of conductive elements such as bonding wires, and an encapsulant made of a resin material (such as epoxy resin) for encapsulating the chip and the bonding wires to protect them against damage from external moisture and contaminants. The semiconductor package further comprises a plurality of array-arranged solder balls implanted on an opposite side of the substrate. Such semiconductor package having the solder balls is customarily referred to as Ball Grid Array (BGA) package, wherein the solder balls serve as input/output (I/O) terminals for electrically connecting the chip to an external device such as a printed circuit board (PCB). Since the semiconductor package has a height including a thickness of the encapsulant for encapsulating the chip and the bonding wires, a thickness of the substrate, and a height of the solder balls, an overall size of the semiconductor package is hard to be further reduced.

In order to effectively diminish the size of the semiconductor package, U.S. Pat. No. 6,218,731 has disclosed a window-type BGA (WBGA) package, as shown in FIG. 1E, which comprises a semiconductor chip 10 mounted on an upper surface 100 of a substrate 1 via an adhesive 13, wherein the chip 10 covers an opening 103 of the substrate 1 and is electrically connected to a lower surface 101 of the substrate 10 by a plurality of bonding wires 14 passing through the opening 103. The chip 10 and the bonding wires 14 are respectively encapsulated by an upper encapsulant 15 and a lower encapsulant 16. A plurality of solder balls 17 are implanted on the lower surface 101 at areas not encapsulated by the lower encapsulant 16.

The foregoing WBGA package can be fabricated by steps shown in FIGS. 1A to 1E.

Referring to FIG. 1A, a substrate strip Z comprising a plurality of substrates 1 is provided, wherein each of the substrates 1 has an opening 103 penetrating therethrough, and the opening 103 is preferably rectangular. Next, a chip-bonding process and a wire-bonding process are performed. During the chip-bonding process, at least one chip 10 is mounted to an upper surface 100 of each of the substrates 1 via an adhesive 13 and covers the opening 103 of each of the substrates 1. During the wire-bonding process, a plurality of bonding wires 14 are formed through the opening 103 of each of the substrates 1 to electrically connect electrode pads 11 on the chip 10 to a lower surface 101 of the corresponding substrate 1.

Referring to FIG. 1B, an encapsulation mold is provided, which comprises an upper mold 18 and a lower mold 19. The upper mold 18 is formed with an upper mold cavity 180, and the lower mold 19 is formed with a plurality of lower mold cavities 190 each of which corresponds to the openings 103 of a row of the substrates 1. The upper mold cavity 180 has a size sufficient to receive all the chips 10 mounted on the substrates 1 therein. Each of the lower mold cavities 190 has a size sufficient to cover all the openings 103 of the corresponding row of the substrates 1 and receive wire loops of the bonding wires 14 protruded on the lower surfaces 101 of the substrates 1. The encapsulation mold is engaged with the substrate strip Z such that the upper mold 18 is clamped to the upper surfaces 100 of the substrates 1 and the lower mold 19 is clamped to the lower surfaces 101 of the substrates 1.

As shown in FIG. 1C, a molding process is performed to inject a resin material (such as epoxy resin) into the lower mold cavities 190 of the lower mold 19 for forming a plurality of lower encapsulants 16. Each of the lower encapsulants 16 fills the openings 103 of the corresponding row of the substrates 1 and encapsulates the corresponding bonding wires 14. The resin material is also injected into the upper mold cavity 180 of the upper mold 18 to form an upper encapsulant 15 for encapsulating all the chips 10 mounted on the substrates 1.

After the molding process is complete, the upper mold 18 and the lower mold 19 are removed from the substrate strip Z, such that areas on the lower surfaces 101 of the substrates 1 not covered by the lower encapsulants 16 are exposed.

Referring to FIG. 1D, a plurality of solder balls 17 are implanted on the exposed areas of the lower surfaces 101 of the substrates 1. After the above chip-boning, wire-bonding, molding and ball-implanting processes are complete, a singulation process is performed to cut the upper encapsulant 15, the substrate strip Z and the lower encapsulants 16 to separate the substrates 1 from each other and form a plurality of WBGA semiconductor packages each having the singulated substrate 1, the chip 10 and the plurality of solder balls 14, as shown in FIG. 1E.

However, the foregoing WBGA package is only suitable for a chip having electrode pads formed on a central area or specific positions of the chip as shown in FIGS. 2A to 2C. If the electrode pads of the chip are not only formed on the central positions but also distributed to other areas of the chip as shown in FIGS. 3A to 3D, fabrication of the WBGA package would become arduous.

In the case of the electrode pads being disposed on both the central and other areas of the chip as disclosed in U.S. Pat. No. 5,777,391, a substrate for carrying the chip must be formed with openings penetrating through the substrate at positions corresponding to the electrode pads of the chip such that bonding wires can pass through the openings of the substrate to electrically connect the electrode pads of the chip to the substrate. However, the provision of openings through the substrate causes design complexity and fabrication difficulty of a circuit layout of the substrate. The more openings being formed, the more fragile the substrate becomes and the less space of the substrate for accommodating circuits is. This thus affects quality and performance of the package and costs and yields of the fabrication processes.

For example, if electrode pads on an active surface of a chip have an arrangement shown in FIG. 3A, after completing chip-bonding and wire-bonding processes for the chip 40, a molding process is performed as shown in FIG. 4A wherein a lower mold 49 must be formed with mold cavities corresponding in position to substrate openings 403 and bonding wires 44. The lower mold 49 becomes more complicated when more substrate openings 403 and bonding wires 44 are provided, and various types of lower molds 49 are required in response to different arrangements of the substrate openings 403 and bonding wires 44. If the substrate is formed with too many openings, areas of the substrate being clamped by the lower mold 49 are decreased during the molding process to thereby increase a chance of resin flashes, such that the reliability of the package is reduced.

FIG. 4B shows a complete WBGA package structure obtained after molding and ball-implanting processes, wherein a size of solder balls 47 is limited by an interval D between adjacent lower encapsulants 46. As such, if more substrate openings 403 are formed, the interval D is reduced and areas for implanting the solder balls 47 become restricted, thereby adversely affecting a ball-implantation space and design of the package.

### SUMMARY OF THE INVENTION

In light of the foregoing drawbacks in the conventional technology, an objective of the present invention is to provide a semiconductor package and a fabrication method of the same, which use both conductive bumps and bonding wires to electrically connect a chip to a substrate so as to reduce the number of openings of a WBGA package substrate, such that the complexity of mold design and the fabrication costs are reduced.

Another objective of the present invention is to provide a semiconductor package and a fabrication method of the same, which use both conductive bumps and bonding wires to electrically connect a chip to a substrate so as to reduce the number of openings of a WBGA package substrate, such that the complexity of substrate design and fabrication is reduced and the strength of substrate structure is maintained.

Still another objective of the present invention is to provide a semiconductor package and a fabrication method of the same, which can prevent decrease in areas being clamped by a mold, thereby reducing a chance of resin flashes during a molding process and maintaining the fabrication yields.

A further objective of the present invention is to provide a semiconductor package and a fabrication method of the same, which can provide sufficient areas for implanting solder balls so as not to affect a ball-implantation arrangement.

A further objective of the present invention is to provide a semiconductor package and a fabrication method of the same, which use both conductive bumps and bonding wires to electrically connect a chip to a substrate so as to improve an electrically conductive function of electronic elements.

In order to achieve the above and other objectives, the present invention proposes a semiconductor package, comprising: a substrate having a first surface, a corresponding second surface, and at least one opening penetrating through the substrate; a chip having an active surface with a plurality of electrode pads being formed thereon, wherein a part of the electrode pads are mounted and electrically connected to the first surface of the substrate by conductive bumps, and the rest of the electrode pads are electrically connected to the second surface of the substrate by bonding wires passing through the opening of the substrate; a first encapsulant formed on the first surface of the substrate for encapsulating the chip; a second encapsulant formed on the second surface of the substrate for encapsulating the bonding wires; and a plurality of solder balls implanted on the second surface of the substrate.

The substrate has the first surface and the corresponding second surface, and the opening of the substrate penetrates through the first and second surfaces. A plurality of conductive pads are formed on the first and second surfaces of the substrate, wherein the conductive pads on the first surface of the substrate correspond in position to the part of the electrode pads of the chip and are electrically connected to the chip via the conductive bumps, and the conductive pads on the second surface of the substrate are electrically connected to the rest of the electrode pads of the chip via the bonding wires.

The present invention also proposes a fabrication method of a semiconductor package, comprising the steps of: providing a chip having an active surface formed with a plurality of electrode pads, and a substrate having a first surface and a corresponding second surface, wherein a part of the electrode pads are formed with conductive bumps thereon respectively, and the substrate further includes at least one opening penetrating therethrough; mounting the part of the electrode pads of the chip to the first surface of the substrate via the conductive bumps, and electrically connecting the rest of the electrode pads of the chip to the second surface of the substrate via bonding wires passing through the opening of the substrate; performing a molding process to respectively form a first encapsulant on the first surface of the substrate for encapsulating the chip and form a second encapsulant on the second surface of the substrate for encapsulating the bonding wires; and implanting a plurality of solder balls on the second surface of the substrate.

Therefore, the semiconductor package and the fabrication method of the same in the present invention are primarily used for a WBGA semiconductor package having a chip with electrode pads being formed not only on a central area of an active surface thereof. In order to electrically connect the chip to a substrate, a part of the electrode pads of the chip are firstly mounted and electrically connected to a first surface of the substrate via conductive bumps in a flip-chip manner, and then the rest of the electrode pads are electrically connected to a second surface of the substrate via bonding wires. This arrangement utilizes both conductive bumps and bonding wires for electrically connecting the chip to the substrate according to locations and distribution areas of the electrode pads of the chip to thereby decrease the number of substrate openings being needed, such that the complexity of mold design, the packaging costs, and the difficulty in substrate design and fabrication are reduced, and the strength of substrate structure is maintained. By the decrease in the number of substrate openings, sufficient areas for implanting solder balls are provided so as not to affect a ball-implantation arrangement of the semiconductor package.

### BRIEF DESCRIPTION OF THE DRAWINGS

The present invention can be more fully understood by reading the following detailed description of the preferred embodiments, with reference made to the accompanying drawings, wherein:

FIGS. 1A to 1E (PRIOR ART) are schematic diagrams showing the fabrication steps of a conventional WBGA package;

FIGS. 2A to 2C (PRIOR ART) are plane views showing electrode pads being arranged on central areas of chips;

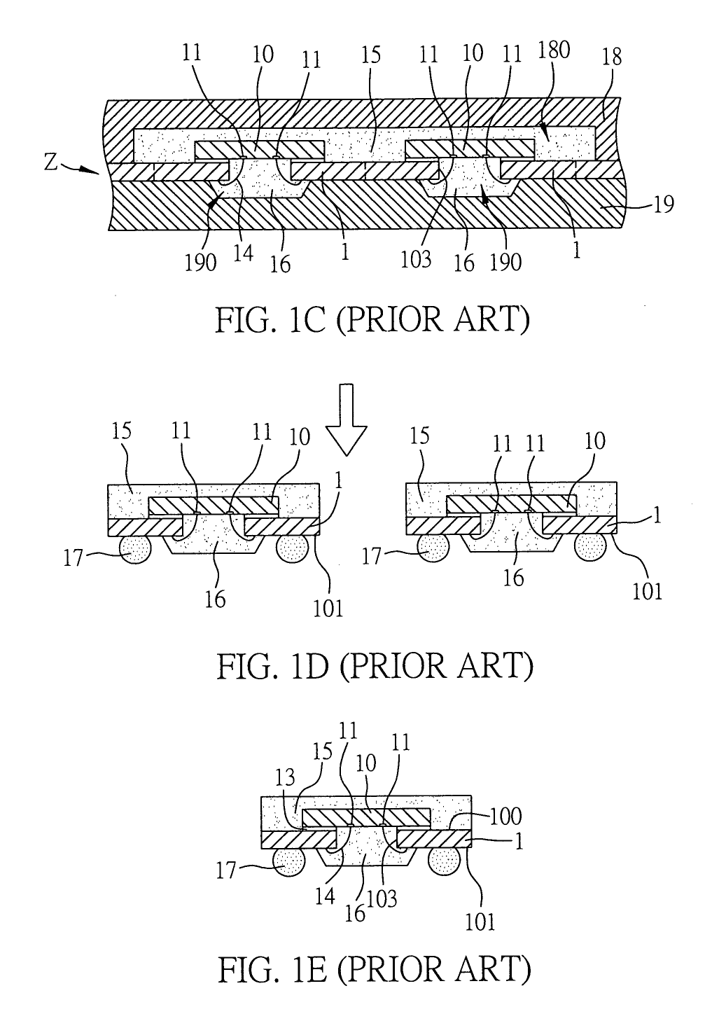

FIGS. 3A to 3D (PRIOR ART) are plane views showing electrode pads being arranged on both central and other areas of chips;

FIG. 4A (PRIOR ART) is a cross-sectional view showing a package structure having the chip of FIG. 3A during a molding process;

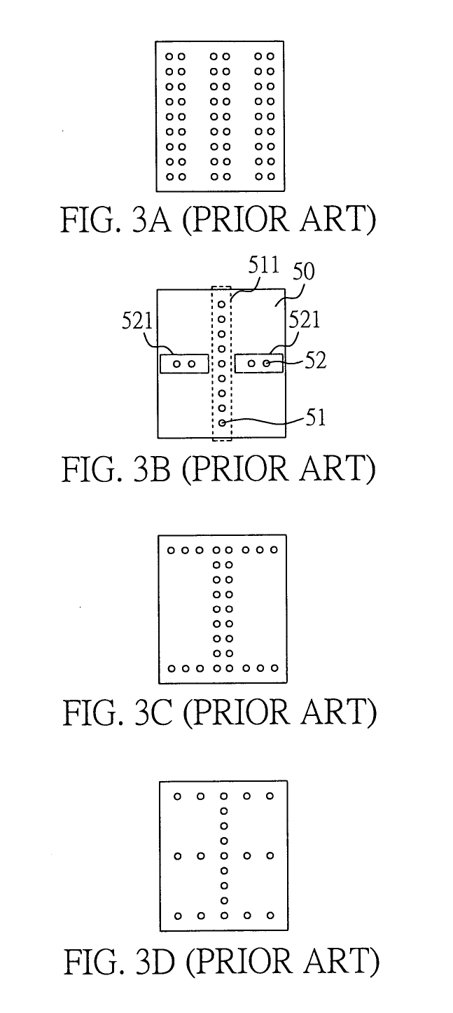

FIG. 4B (PRIOR ART) is a cross-sectional view showing a complete WBGA package structure after molding and ball-implanting;

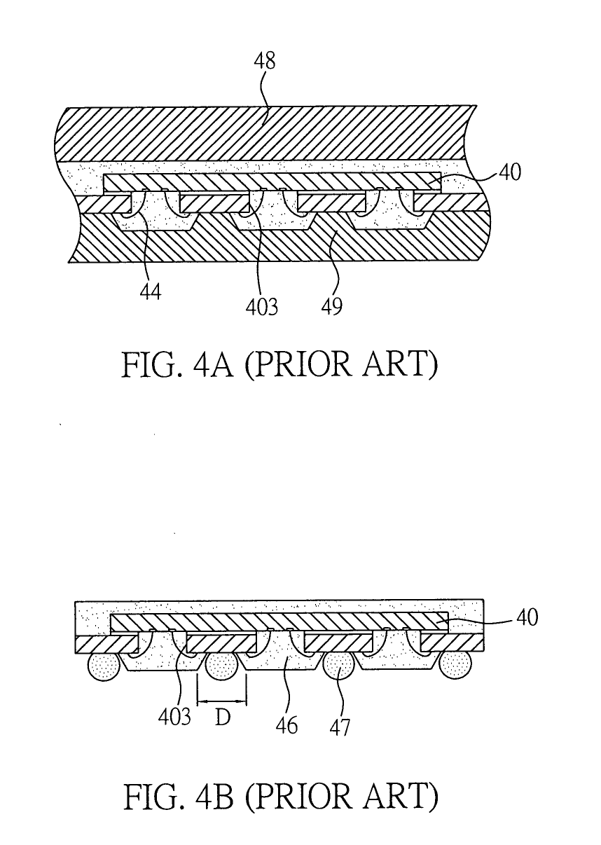

FIGS. 5A to 5D are cross-sectional views showing steps of a fabrication method of a semiconductor package in accordance with a first preferred embodiment of the present invention; and

FIG. 6 is a cross-sectional view showing a semiconductor package in accordance with a second preferred embodiment of the present invention.

### DETAILED DESCRIPTION

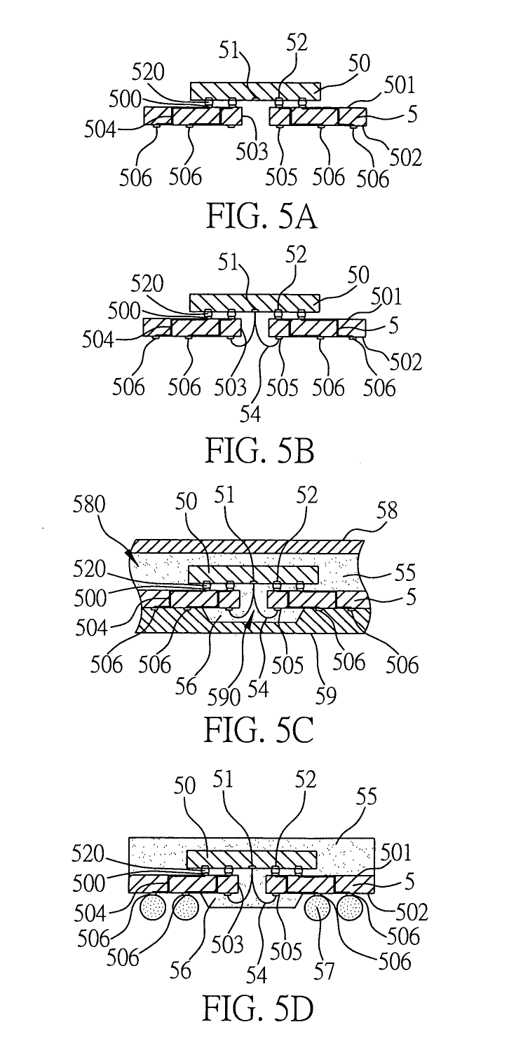

Referring to FIG. 5D showing a cross-sectional view of a semiconductor package in accordance with a first preferred embodiment of the present invention, the semiconductor package includes a substrate 5, a semiconductor chip 50, conductive bumps 520, bonding wires 54, encapsulants 55, 56, and a plurality of solder balls 57.

The substrate 5 has a first surface 501 and a corresponding second surface 502, and is formed with at least one opening 503 penetrating through the first and second surfaces 501, 502.

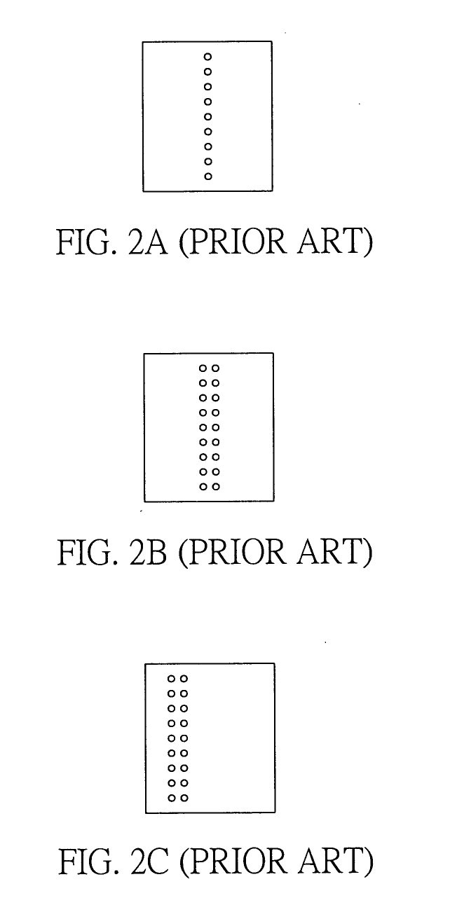

The chip 50 can have an arrangement shown in FIG. 3B. The chip 50 has an active surface formed with a plurality of electrode pads 51, 52 arranged in a cross. The electrode pads 51, 52 include a first group of electrode pads 51 located in a first electrode pad area 511 predetermined for performing a wire-bonding process, and a second group of electrode pads 52 located in a second electrode pad area 521 predetermined for performing a flip-chip electrically connecting process.

A plurality of conductive pads 500, 505 are formed on the first surface 501 and the second surface 502 of the substrate 5, respectively. The conductive pads 500 on the first surface 501 of the substrate 5 are electrically connected to a part of the conductive pads 505 on the second surface 502 by interlayer conductive structures such as conductive vias or plated through holes (PTHs). Further, the conductive pads 500 on the first surface 501 of the substrate 5 correspond in position to the electrode pads 52 located in the second electrode pad area 521 of the chip 50 and are directly electrically connected to the chip 50 via the conductive bumps 520 so as to improve the electrical performance. The conductive pads 505 on the second surface 502 of the substrate 5 are electrically connected to the electrode pads 51 located in the first electrode pad area 511 of the chip 50 via the bonding wires 54.

The encapsulants 55, 56 include a first encapsulant 55 formed on the first surface 501 of the substrate 5 for encapsulating the chip 50, and a second encapsulant 56 formed on the second surface 502 of the substrate 5 for encapsulating the bonding wires 54.

The plurality of solder balls 57 are implanted on ball pads 506 of the second surface 502 of the substrate 5 so as to allow the chip 50 to be electrically connected to an external device via the solder balls 57.

FIGS. 5A to 5D are cross-sectional views showing steps of a fabrication method of the semiconductor package in the present invention.

Referring to FIG. 5A, a chip 50 with a plurality of electrode pads 51, 52 being formed on an active surface thereof and a substrate 5 having a first surface 501 and a corresponding second surface 502 are provided. The substrate 5 further comprises at least one opening 503 penetrating through the first and second surfaces 501, 502, and a plurality of conductive pads 500, 505 formed on the first and second surfaces 501, 502 respectively. The conductive pads 500 on the first surface 501 of the substrate 5 can be electrically connected to a part of the conductive pads 505 on the second surface 502 by interlayer conductive structures 504 such as conductive vias or PTHs. The electrode pads 52 of the chip 50 are electrically connected to the conductive pads 500 on the first surface 501 of the substrate 5 by conductive bumps 520 in a flip-chip manner, and the chip 50 covers one end of the opening 503 of the substrate 5, with the electrode pads 51 of the chip 50 being exposed to the opening 503.

The chip 50 can be, but not limited to, a semiconductor chip shown in FIG. 3B. The electrode pads 51, 52 of the chip 50 include a first group of electrode pads 51 located in a first electrode pad area 511 predetermined for performing a wire-bonding process, and a second group of electrode pads 52 located in a second electrode pad area 521 predetermined for performing a flip-chip electrically connecting process. The electrode pads 52 in the second electrode pad area 521 of the chip 50 are electrically connected to the substrate 5 via the conductive bumps 520. The conductive bumps 520 can be solder bumps or gold bumps. For example, solder bumps can be formed on the electrode pads 52 of the chip 50 and a pre-solder material is formed on the conductive pads 500 on the first surface 501 of the substrate 5 respectively so as to allow the chip 50 to be mounted and electrically connected to the first surface 501 of the substrate 5 by a reflow process. Alternatively, a relatively more cost-effective stud bonding process can be performed by using a capillary of a wire-bonding machine to clamp a gold wire and attach a spherical end of the gold wire to each of the electrode pads 52 of the chip 50 to form a gold bump such that the electrode pads 52 in the second electrode pad area 521 of the chip 50 are mounted and electrically connected to the first surface 501 of the substrate 5 via the gold bumps.

Referring to FIG. 5B, the electrode pads 51 in the first electrode pad area 511 of the chip 50, which are exposed to the opening 503 of the substrate 5, are electrically connected to the conductive pads 505 on the second surface 502 of the substrate 5 via bonding wires 54 passing through the opening 503.

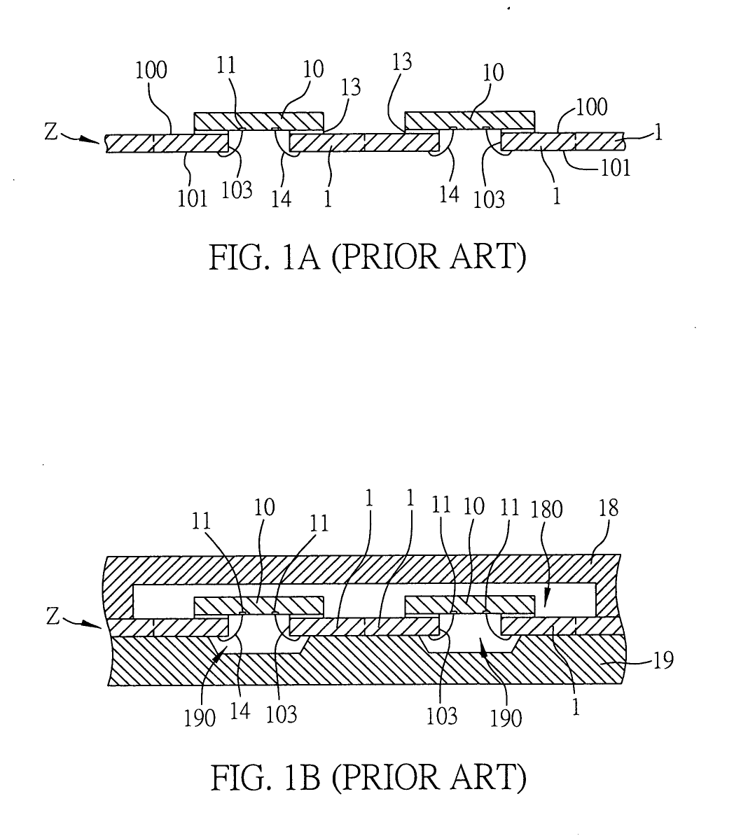

Referring to FIG. 5C, a molding process is performed by using an encapsulation mold comprising an upper mold 58 and a lower mold 59. The upper mold 58 is formed with an upper mold cavity 580 having a size sufficient to receive the chip 50 mounted on the substrate 5 therein, and the lower mold 59 is formed with a lower mold cavity 590 having a size sufficient to cover the opening 503 of the substrate 5 and receive wire loops of the bonding wires 54 protruded on the second surface 502 of the substrate 5. A resin material (such as epoxy resin) is injected into the upper and lower mold cavities 580, 590 to respectively form a first encapsulant 55 on the first surface 501 of the substrate 5 for encapsulating the chip 50 and form a second encapsulant 56 on the second surface 502 of the substrate 5 for encapsulating the bonding wires 54. In this embodiment, although the electrode pads are distributed on wide areas of the active surface of the chip, as the electrode pads located relatively at peripheral areas of the chip are firstly electrically connected to the first surface of the substrate by a flip-chip technique and then the electrode pads located at a central area of the chip are electrically connected to the second surface of the substrate by a wire-bonding technique, it only needs to form an opening through a central area of the substrate as similar to a conventional WBGA package shown in FIG. 1E, such that the molding process can be performed using a conventional encapsulation mold to thereby reduce the costs, and relatively larger areas on the second surface of the substrate are provided for subsequent implanting solder balls.

Referring to FIG. 5D, a plurality of solder balls 57 are implanted on ball pads 506 of the second surface 502 of the substrate 5 not encapsulated by the second encapsulant 56. It should be noted that the fabrication method in the present invention can be used to form a single package structure or form a plurality of package structures in a batch-type manner.

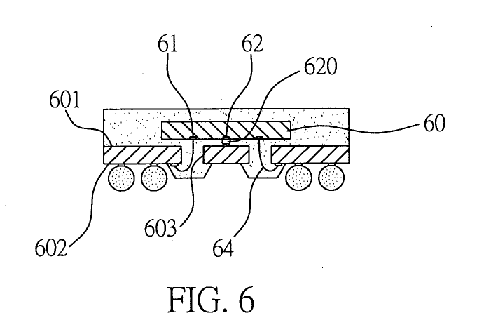

FIG. 6 shows a cross-sectional view of a semiconductor package according to a second preferred embodiment of the present invention. The semiconductor package of the second embodiment is substantially the same in structure and fabrication thereof as that of the first embodiment, with a primary difference in that according to practical conditions such as locations, intervals and fabrication requirements of electrode pads of a chip, the flip-chip technique and the wire-bonding technique in the second embodiment are applied to different electrode pads of the chip as compared to the first embodiment. For example, as shown in FIG. 6, if electrode pads 62 located in a central area of a chip 60 are relatively sparse, a relatively more cost-effective and simpler stud bonding process can be employed to implant gold bumps on the electrode pads 62 located in the central area of the chip 60, allowing the electrode pads 62 to be mounted and electrically connected to a first surface 601 of a substrate 6 in a flip-chip manner. Further, openings 603 are formed through the substrate 6 at positions corresponding to the other electrode pads 61 located in areas other than the central area of the chip 60, such that the electrode pads 61 of the chip 60 are exposed to the openings 603 and are electrically connected to a second surface 602 of the substrate 6 via bonding wires 64 passing through the openings 603. Then a molding process and a ball-implanting process are performed. Similarly, the package structure of the second embodiment can be fabricated in a single-package forming manner or a batch-type manner, wherein a singulation process is further required to form a plurality of individual package units for the batch-type manner.

Therefore, the semiconductor package and the fabrication method of the same in the present invention are primarily used for a WBGA semiconductor package having a chip with electrode pads being formed not only in a central area of an active surface thereof. For electrically connecting the chip to a substrate, a part of the electrode pads of the chip are firstly mounted and electrically connected to a first surface of the substrate via conductive bumps, and then the rest of the electrode pads of the chip are electrically connected to a second surface of the substrate via bonding wires. This arrangement can decrease the number of substrate openings being needed, such that problems caused in a conventional WBGA semiconductor package such as complexity of substrate circuit layout and fabrication, increase in mold costs, and an increased chance of resin flashes can be solved as there is no need to form many openings in the substrate at positions corresponding to the electrode pads of the chip unlike the conventional WBGA semiconductor package, thereby not affecting a subsequent ball-implantation arrangement on the substrate in the present invention.

The invention has been described using exemplary preferred embodiments. However, it is to be understood that the scope of the invention is not limited to the disclosed embodiments. On the contrary, it is intended to cover various modifications and similar arrangement. The scope of the claims therefore should be accorded the broadest interpretation so as to encompass all such modifications and similar arrangements.

What is claimed is:

1. A fabrication method of a semiconductor package, comprising:
providing a chip having an active surface formed with a plurality of electrode pads, and a substrate having a first surface, a corresponding second surface and at least one opening penetrating through the substrate;
mounting and electrically connecting a part of the electrode pads of the chip to the first surface of the substrate via conductive bumps in a flip-chip manner, and electrically connecting the rest of the electrode pads of the chip to the second surface of the substrate via bonding wires passing through the opening of the substrate;
performing a molding process to respectively form a first encapsulant on the first surface of the substrate for encapsulating the chip and form a second encapsulant on the second surface of the substrate for encapsulating the bonding wires; and
implanting a plurality of solder balls on the second surface of the substrate.

2. The method of claim 1, wherein the semiconductor package is a window-type ball grid array (WBGA) semiconductor package.

3. The method of claim 1, wherein the substrate further comprises a plurality of conductive pads formed on the first and second surfaces thereof, such that the part of the electrode pads of the chip are electrically connected to the conductive pads on the first surface of the substrate via the conductive bumps in the flip-chip manner and the chip covers one end of the opening of the substrate, and the rest of the electrode pads of the chip are exposed to the opening of the substrate and are electrically connected to the conductive pads on the second surface of the substrate via the bonding wires passing through the opening.

4. The method of claim 1, wherein the conductive bumps are solder bumps or gold bumps.

5. The method of claim 1, wherein the chip is electrically connected to the substrate in the flip-chip manner that solder bumps are formed on the electrode pads of the chip and a pre-solder material is formed on the first surface of the substrate, and a reflow process is performed to mount and electrically connect the chip to the first surface of the substrate.

6. The method of claim 1, wherein the chip is electrically connected to the substrate in the flip-chip manner that a stud bonding process is performed by a capillary to clamp a gold wire and attach a spherical end of the gold wire to each of the part of the electrode pads of the chip to form a gold bump, such that the chip is electrically connected to the first surface of the substrate via the gold bumps.

7. The method of claim 1, which is for forming a single package structure or forming a plurality of package structures in a batch-type manner.

8. A semiconductor package, comprising:
a substrate having a first surface, a corresponding second surface, and at least one opening penetrating through the substrate;
a chip having a plurality of electrode pads formed on an active surface thereof, wherein a part of the electrode pads are mounted and electrically connected to the first surface of the substrate via conductive bumps, and the rest of the electrode pads are electrically connected to the second surface of the substrate via bonding wires passing through the opening of the substrate;
a first encapsulant formed on the first surface of the substrate, for encapsulating the chip;
a second encapsulant formed on the second surface of the substrate, for encapsulating the bonding wires; and
a plurality of solder balls implanted on the second surface of the substrate.

9. The semiconductor package of claim 8, which is a WBGA semiconductor package.

10. The semiconductor package of claim 8, wherein the substrate further comprises a plurality of conductive pads formed on the first and second surfaces thereof, such that the part of the electrode pads of the chip are electrically connected to the conductive pads on the first surface of the substrate via the conductive bumps and the chip covers one end of the opening of the substrate, and the rest of the electrode pads of the chip are exposed to the opening of the substrate and are electrically connected to the conductive pads on the second surface of the substrate via the bonding wires passing through the opening.

11. The semiconductor package of claim 8, wherein the conductive bumps are solder bumps or gold bumps.

12. The semiconductor package of claim 8, wherein solder bumps are formed on the electrode pads of the chip and a pre-solder material is formed on the first surface of the substrate so as to mount and electrically connect the chip to the first surface of the substrate via a reflow process.

13. The semiconductor package of claim 8, wherein a capillary is provided in a stud bonding process to clamp a gold wire and attach a spherical end of the gold wire to each of the part of the electrode pads of the chip to form a gold bump, such that the chip is electrically connected to the first surface of the substrate via the gold bumps.
